(19) United States
(12) Patent Application Publication
(10) Pub. No.: US 2021/0022246 A1
(43) Pub. Date: Jan. 21, 2021

(54) METHOD FOR MANUFACTURING FLEXIBLE PRINTED CIRCUIT TERMINAL CONNECTION STRUCTURES

(71) Applicant: LENOVO (SINGAPORE) PTE. LTD., Singapore (SG)

(72) Inventors: Wenjin Niu, Kanagawa (JP); Takehito Yamauchi, Kanagawa (JP); Kazutoshi Sugisawa, Kanagawa (JP); Shigehiro Horiuchi, Kanagawa (JP)

(21) Appl. No.: 16/933,463

(22) Filed: Jul. 20, 2020

(30) Foreign Application Priority Data
Jul. 18, 2019 (JP) 2019-132747

(51) Int. Cl. H05K 1/11; H01R 9/18; H05K 1/02; H05K 3/36

(52) U.S. Cl. CPC H05K 1/118; H01R 9/18; H05K 1/0281; H05K 2201/10598; H05K 2201/10265; H05K 2201/10409; H05K 3/365

(57) ABSTRACT

A flexible printed circuit (FPC) terminal connection structure is provided. The FPC terminal connection structure includes a base material; a substrate secured to the base material, wherein the substrate includes a second terminal group on one surface thereof an FPC including a first terminal group on a first surface thereof, corresponding terminals of the first terminal group and the second terminal group being in contact with each other; a flat spring disposed on top of a first position that interferes with at least the first terminal group on a second surface of the FPC; and a fastening member for fastening the flat spring and the FPC to the base material at a second position different from the first position.

### PRIORITY CLAIM

The present application claims benefit of priority under 35 U.S.C. §§ 120, 365 to the previously tiled Japanese Patent Application No. JP2019-132747 with a priority date of Jul. 18, 2019, which is incorporated by reference herein.

### TECHNICAL FIELD

The present invention relates to flexible printed circuit (FPC) terminal connection structures in general, and in particular to a method for manufacturing a FPC terminal connection structure.

### BACKGROUND

Flexible printed circuit (FPC) terminal connection structures are known. In a conventional FPC terminal connection structure, a BtoB® connector of a flexible printed circuit board is connected to a BtoB® connector of a substrate. But such a conventional FPC terminal connection structure has much rooms for improvement.

The present disclosure provides a method for manufacturing a simplified, easy-to-assemble FPC terminal connection structure.

### SUMMARY

In accordance with an embodiment of the present disclosure, a FPC terminal connection structure includes a base material; a substrate secured to the base material, the substrate including a second terminal group on one surface thereof; an FPC including a first terminal group on a first surface thereof, respective corresponding terminals of the first terminal group and the second terminal group being in contact with each other; a flat spring disposed on top of a first position that is a position that interferes with at least the first terminal group on a second surface of the FPC; and a fastening member used to fasten the flat spring and the FPC to the base material at a second position different from the first position. By the flat spring being fastened to the base material with the fastening member, the first terminal group of the FPC is biased toward the second terminal group of the substrate.

All features and advantages of the present disclosure will become apparent in the following detailed written description.

### BRIEF DESCRIPTION OF THE DRAWINGS

The invention itself, as well as a preferred mode of use, further objects, and advantages thereof, will best be understood by reference to the following detailed description of an illustrative embodiment when read in conjunction with the accompanying drawings, wherein:

FIG. 1 is a perspective view of a FPC terminal connection structure, according to one embodiment;

FIG. 2 is an exploded perspective view illustrating the FPC terminal connection structure, according to one embodiment;

FIG. 3 is a cross-sectional view illustrating the FPC terminal connection structure, according to one embodiment;

FIG. 4 is a cross-sectional view illustrating a first modification example of the FPC terminal connection structure, according to one embodiment; and

FIG. 5 is a cross-sectional view illustrating a second modification example of the FPC terminal connection structure, according to one embodiment.

### DETAILED DESCRIPTION

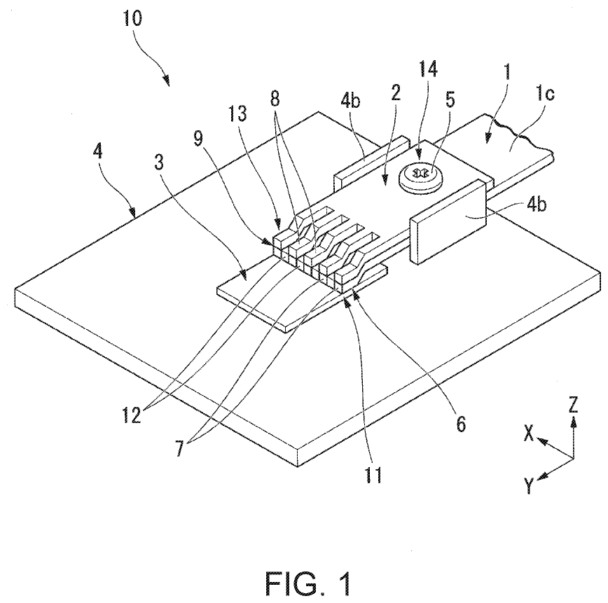

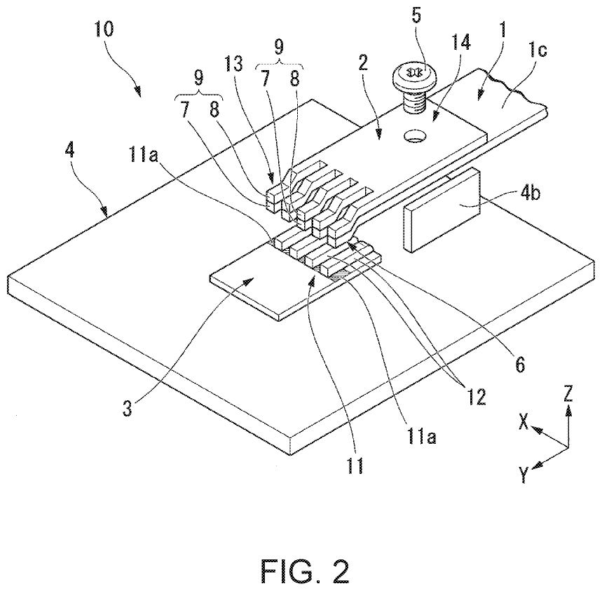

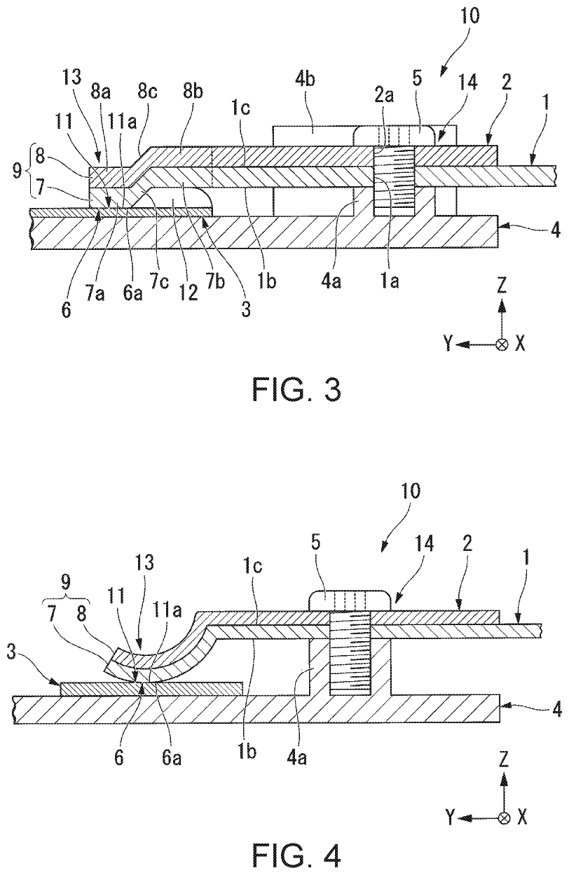

FIG. 1 is a perspective view of a flexible printed circuit (FPC) terminal connection structure, according to one embodiment. FIGS. 2 and 3 are an exploded perspective view and a cross-sectional view of the FPC terminal connection structure from FIG. 1, respectively. As illustrated in FIGS. 1 to 3, the FPC terminal connection structure 10 includes an FPC 1, a flat spring 2 disposed on top of the FPC 1, a base material 4, a substrate 3, and a fastening member 5. The FPC 1 is formed into a film having flexibility, and is deformable with keeping electrical characteristics (function). The FPC 1 has, for example, one conductive layer. The FPC 1 extends in a predetermined direction.

### I. Definition of Directions

In the present embodiment, each configuration is described with an XYZ Cartesian coordinate system set.

A Y-axis direction is the above-described predetermined direction in which the FPC 1 extends, i.e., an extending direction of the FPC 1. In the present embodiment, the Y-axis direction may sometimes be referred to as a front-rear direction. In this case, in the front-rear direction, a direction (the −Y side) from an end of the FPC 1 in the extending direction to the part other than the end is the rear, and a direction (the −Y side) from the part other than the end of the FPC 1 in the extending direction to the end is the front.

A Z-axis direction is a thickness direction of the FPC 1. In the present embodiment, the Z-axis direction may sometimes be referred to as a top-bottom direction. In this case, in the top-bottom direction, a direction (the −Z side) from the FPC 1 to the flat spring 2 is the top, and a direction (the −Z side) from the flat spring 2 to the FPC 1 is the bottom.

An X-axis direction is a width direction of the FPC 1 perpendicular to the extending direction and the thickness direction. In the present embodiment, the X-axis direction may sometimes be referred to as a right-left direction.

### II. FPC

The FPC 1 has a first surface 1b and a second surface 1c that face the thickness direction. The first surface 1b and the second surface 1c face the opposite sides in the thickness direction. In the present embodiment, the first surface 1b is a lower surface of the FPC 1, and the second surface 1c is an upper surface of the FPC 1. The FPC 1 includes a first terminal group 6 on the first surface 1b. The first terminal group 6 constitutes part of the conductive layer of the FPC 1. The first terminal group 6 is disposed at a front end of the FPC 1. The first terminal group 6 includes a plurality of first terminals 6a. The plurality of first terminals 6a is disposed in the width direction of the FPC 1 so as to be spaced apart from one another. Each of the first terminals 6a is exposed on the lower surface of the FPC 1, i.e., the first surface 1b.

The FPC 1 includes a plurality of terminal attachment parts 7. In an example illustrated in the drawings, the FPC 1 includes five terminal attachment parts 7. The plurality of terminal attachment parts 7 is disposed at the front end of the FPC 1. Each of the terminal attachment parts 7 extends in the front-rear direction. The plurality of terminal attachment parts 7 is disposed in the width direction of the FPC 1 so as to be spaced apart from one another. The front end of the FPC 1 is provided with the plurality of terminal attachment parts 7, and thus has a shape like comb teeth. The terminal attachment parts 7 project further toward the substrate 3 than a portion of the FPC 1 other than the terminal attachment parts 7. That is, the terminal attachment parts 7 project further toward the bottom than a portion of the FPC 1 other than the terminal attachment parts 7.

The first terminals 6a of the first terminal group 6 are disposed in the terminal attachment parts 7. In the present embodiment, one first terminal 6a is disposed in one terminal attachment part 7.

As illustrated in FIG. 3, the terminal attachment part 7 includes a first portion 7a, a second portion 7b, and a third portion 7c.

The first portion 7a is disposed at a front end of the terminal attachment part 7. The first portion 7a is located at the bottommost of the terminal attachment part 7. The first portion 7a extends in the front-rear direction. The first terminal 6a of the first terminal group 6 is exposed on a lower surface of the first portion 7a. The lower surface of the first portion 7a is in contact with an upper surface (one surface) of the substrate 3.

The second portion 7b is disposed at a rear end of the terminal attachment part 7. The second portion 7b connects with a portion of the FPC 1 other than the terminal attachment part 7. The second portion 7b extends in the front-rear direction. The second portion 7b is located above the first portion 7a.

The third portion 7c is disposed between the front end and the rear end of the terminal attachment part 7. The third portion 7c extends to be inclined toward the bottom as it comes closer to the front. The third portion 7c connects with a rear end of the first portion 7a and a front end of the second portion 7b.

The FPC 1 has a first through hole 1a. The first through hole 1a runs in the top-bottom direction through a portion of the FPC 1 located behind the terminal attachment parts 7.

The FPC 1 includes a first position 13 and a second position 14. The first position 13 includes a position that interferes (overlaps) with at least the first terminal group 6 when the FPC 1 is viewed from the thickness direction. The first position 13 includes the front end of the FPC 1 in the extending direction. The terminal attachment part 7 is disposed in the first position 13.

The second position 14 is a different position in the FPC 1 from the first position 13. The second position 14 is located behind the first position 13. The first through hole la is disposed in the second position 14.

### III. Flat Spring

The flat spring 2 is elastically deformable. The flat spring 2 is, for example, a metallic plate-like spring member or the like. The flat spring 2 is adhesively secured to the FPC 1. That is, a lower surface of the flat spring 2 and the upper surface (the second surface 1c) of the FPC 1 are secured to each other with an adhesive or the like. The flat spring 2 is disposed on top of the first position 13 that is a position that interferes with at least the first terminal group 6 on the second surface 1c of the FPC 1. In the present embodiment, the flat spring 2 is disposed on the second surface 1c of the FPC 1 on top of and over the first position 13 and the second position 14.

As illustrated in FIGS. 1 to 3, in the present embodiment, a front end of the flat spring 2 is disposed to be even with the front end of the FPC 1. Both ends of the flat spring 2 in the right-left direction are disposed to be even with both ends of the FPC 1 in the right-left direction. A rear end of the flat spring 2 is located in front of a rear end of the FPC 1. The length of the flat spring 2 in the front-rear direction is shorter than the length of the FPC 1 in the front-rear direction.

The flat spring 2 includes a plurality of terminal biasing parts 8. In the example illustrated in the drawings, the flat spring 2 includes five terminal biasing parts 8. The terminal biasing parts 8 are elastically deformable. The plurality of terminal biasing parts 8 is disposed at the front end of the flat spring 2. Each of the terminal biasing parts 8 extends in the front-rear direction. The plurality of terminal biasing parts 8 is disposed in the width direction so as to be spaced apart from one another. The front end of the flat spring 2 is provided with the plurality of terminal biasing parts 8, and thus has a shape like comb teeth. The terminal biasing parts 8 project further toward the substrate 3 than a portion of the flat spring 2 other than the terminal biasing parts 8. That is, the terminal biasing parts 8 project further toward the bottom than a portion of the flat spring 2 other than the terminal biasing parts 8.

The terminal biasing parts 8 are disposed on top of the terminal attachment parts 7 at the first position 13. The terminal biasing part 8 and the terminal attachment part 7 are adhesively secured. A lower surface of the terminal biasing part 8 and an upper surface of the terminal attachment part 7 are secured to each other with an adhesive or the like.

In the present embodiment, a pair of the terminal biasing part 8 and the terminal attachment part 7 stacked in the top-bottom direction may sometimes be referred to as an elastic terminal area 9. That is, the elastic terminal area 9 includes the terminal biasing part 8 and the terminal attachment part 7. A plurality of elastic terminal areas 9 is provided in the width direction so as to be spaced apart from one another. Each of the elastic terminal areas 9 extends in the front-rear direction.

As illustrated in FIG. 3, the terminal biasing part 8 includes a first biasing portion 8a, a second biasing portion 8b, and a third biasing portion 8c.

The first biasing portion 8a is disposed at a front end of the terminal biasing part 8. The first biasing portion 8a is located at the bottommost of the terminal biasing part 8. The first biasing portion 8a extends in the front-rear direction. The first biasing portion 8a is disposed on top of the first portion 7a.

The second biasing portion 8b is disposed at a rear end of the terminal biasing part 8. The second biasing portion 8b connects with a portion of the flat spring 2 other than the terminal biasing part 8. The second biasing portion 8b extends in the front-rear direction. The second biasing portion 8b is located above the first biasing portion 8a. The second biasing portion 8b is disposed on top of the second portion 7b.

The third biasing portion 8c is disposed between the front end and the rear end of the terminal biasing part 8. The third biasing portion 8c extends to be inclined toward the bottom as it comes closer to the front. The third biasing portion 8c connects with a rear end of the first biasing portion 8a and a front end of the second biasing portion 8b. The third biasing portion 8c is disposed on top of the third portion 7c.

The flat spring 2 includes a bent portion between the first position 13 and the second position 14; the bent portion is bent to be closer to the substrate 3 as it comes closer to the first position 13. That is, the bent portion is disposed on the second surface 1c of the FPC 1 between the first position 13 and the second position 14, and is bent toward the bottom as it comes closer to the front. In the present embodiment, the bent portion includes the third biasing portions 8c of the terminal biasing parts 8.

The flat spring 2 has a second through hole 2a. The second through hole 2a runs in the top-bottom direction through a portion of the flat spring 2 located behind the terminal biasing parts 8. The second through hole 2a is disposed above the first through hole 1a, and communicates with the first through hole 1a. The second through hole 2a is disposed in the second position 14 on the second surface 1c of the FPC 1.

### IV. Base Material

The base material 4 is, for example, part of a chassis of an electronic apparatus. The base material 4 may be rephrased as a system unit. As illustrated in FIGS. 1 to 3, in the present embodiment, the base material 4 is formed into a plate.

The base material 4 includes a fixed tubular part 4a and a positioning part 4b.

The fixed tubular part 4a is formed into a tube projecting from an upper surface of the base material 4 toward the top. The lower surface (the first surface 1b) of the FPC 1 is in contact with an upper surface of the fixed tubular part 4a. The fixed tubular part 4a includes an internal thread portion on its inner circumferential surface.

The positioning part 4b is formed into a rib or a plate that projects from the upper surface of the base material 4 toward the top and extends in the front-rear direction. The positioning part 4b can be in contact with at least either the flat spring 2 or the FPC 1 in the width direction of the FPC 1 at a position closer to the second position 14 than the first position 13. In the example illustrated in the drawings, a position of the positioning part 4b in the front-rear direction is the same position as the second position 14 in the front-rear direction. In the present embodiment, a pair of positioning parts 4b is provided in the width direction so as to be spaced apart from each other. The pair of positioning parts 4b is disposed on both sides of the flat spring 2 and the FPC 1 in the width direction.

### V. Substrate

The substrate 3 is provided on the base material 4. The substrate 3 is secured to the upper surface of the base material 4, for example, with double-sided tape or the like. Of a pair of plate surfaces of the substrate 3, one surface faces to the top (the side opposite to the base material 4), and the other surface faces to the bottom and is opposed to the upper surface of the base material 4.

The substrate 3 includes a second terminal group 11 on the one surface. The second terminal group 11 is in contact with the first terminal group 6 of the FPC 1. The second terminal group 11 is electrically connected to the first terminal group 6. As illustrated in FIGS. 2 and 3, the second terminal group 11 includes a plurality of second terminals 11a. The plurality of second terminals 11a is disposed in the width direction so as to be spaced apart from one another. Each of the second terminals 11a is exposed on the upper surface (the one surface) of the substrate 3. The second terminals 11a are in contact with the first terminals 6a. That is, respective corresponding terminals (the first terminals 6a and the second terminals 11a) of the first terminal group 6 and the second terminal group 11 are in contact with each other.

The substrate 3 includes an insulating portion 12. The insulating portion 12 is disposed between the terminal attachment parts 7 adjacent in the width direction. The insulating portion 12 projects from the upper surface of the substrate 3 toward the top and extends in the front-rear direction. In the present embodiment, the insulating portion 12 is formed into a protruding portion, i.e., a rib. The length of the insulating portion 12 in the front-rear direction is substantially the same as the length of the elastic terminal area 9 in the front-rear direction. A plurality of insulating portions 12 is provided in the width direction so as to be spaced apart from one another. The insulating portions 12 and the second terminals 11a are alternately arranged in the width direction on the upper surface of the substrate 3.

### VI. Fastening Member

As illustrated in FIGS. 1 to 3, the fastening member 5 fastens the flat spring 2 and the FPC 1 to the base material 4 at the second position 14 different from the first position 13. In the present embodiment, the fastening member 5 is a screw. The fastening member 5 includes an external thread portion on its outer circumferential surface. The external thread portion of the fastening member 5 is inserted into the second through hole 2a and the first through hole la and screwed into the internal thread portion of the fixed tubular part 4a. One fastening member 5 is provided.

By the flat spring 2 being fastened to the base material 4 with the fastening member 5, the first terminal group 6 of the FPC 1 is biased toward the second terminal group 11 of the substrate 3. Specifically, by the flat spring 2 being fastened to the base material 4 with the fastening member 5, the terminal biasing parts 8 of the flat spring 2 are elastically deformed, and the first terminals 6a disposed in the terminal attachment parts 7 are biased toward the second terminals 11a of the substrate 3.

### VII. Method for Manufacturing FPC Terminal Connection Structure

Subsequently, the method for manufacturing the FPC terminal connection structure 10 is described.

The method for manufacturing the FPC terminal connection structure 10 according to the present embodiment includes a bonding process, an elastic-terminal-area forming process, a mounting process, and a connecting process.

In the bonding process, the flat spring 2 is bonded to at least the first position 13 on the second surface 1c of the FPC 1 with an adhesive or the like, and is integrated with the FPC 1. In the present embodiment, the lower surface of the flat spring 2 is bonded to over the first position 13 and the second position 14 on the second surface 1c of the FPC 1.

In the elastic-terminal-area forming process, a plurality of spaced-apart elastic terminal areas 9 is formed by making slits in the flat spring 2 and the FPC 1, which have been integrated through the bonding process, at the first position 13.

In the mounting process, the flat spring 2 and the FPC 1 are inserted between the pair of positioning parts 4b and mounted on the base material 4, and thus the first terminal group 6 of the FPC 1 and the second terminal group 11 of the substrate 3 are opposed to each other in the top-bottom direction.

In the connecting process, the flat spring 2 and the FPC 1 are fastened to the base material 4 at the second position 14 with the fastening member 5 to bring the first terminal group 6 of the FPC 1 and the second terminal group 11 of the substrate 3 into contact with each other.

Specifically, in this connecting process, by the flat spring 2 being fastened to the base material 4 with the fastening member 5, the first terminals 6a disposed in the respective terminal attachment parts 7 of the elastic terminal areas 9 are pressed against the second terminal group 11 (the second terminals 11a) by the biasing force of the terminal biasing parts 8.

In the FPC terminal connection structure 10 according to the present embodiment described above, when the flat spring 2 and the FPC 1 are fastened to the base material 4 with the fastening member 5, the first terminal group 6 of the FPC 1 is biased toward the second terminal group 11 of the substrate 3 by means of elastic deformation of the flat spring 2, etc. That is, the first terminal group 6 is pressed against the second terminal group 11 by the biasing force of the flat spring 2, and thus the first terminal group 6 and the second terminal group 11 come in contact with each other stably, and this contact state is maintained favorably.

According to the present embodiment, there is no need to provide a member such as a connector (a male connector and a female connector) conventionally used for connection between terminal, and the structure can be simplified. Furthermore, in the present embodiment, no connector is used, which makes it easier to achieve space conservation and cost reduction of the FPC terminal connection structure 10. Moreover, according to the present embodiment, positioning of the first terminal group 6 and the second terminal group 11 and the work of fastening the FPC 1 to the base material 4 are easier than assembly of, for example, a BtoB« connector, and thus the ease of assembly is improved.

Specifically, the assembly of a BtoB« connector requires complicated work, for example, a long enough length of an FPC to which a connector is connected is secured in advance, and a worker holds up a pair of connectors before his eyes and connects the connectors while visually adjusting their positions, and then mounts the connectors and the FPC on a base material, and secures an excess length of the FPC to the base material with double-sided tape or the like.

On the other hand, in the present embodiment, by fastening the flat spring 2 and the FPC 1 to the base material 4 with the fastening member 5, the first terminal group 6 of the FPC 1 and the second terminal group 11 of the substrate 3 are connected while their positions are adjusted on the base material 4. That is, there is no need to secure a long enough length of the FPC 1 for the assembly work, and thus it is possible to reduce an amount of material used for the FPC 1. Furthermore, the FPC 1 has no excess length, and thus it is possible to eliminate the work of securing the FPC 1 to the base material 4 with double-sided tape or the like.

Furthermore, in the present embodiment, the elastic terminal areas 9 each include a pair of the terminal attachment part 7 and the terminal biasing part 8. Specifically, the FPC 1 includes the plurality of terminal attachment parts 7, and the flat spring 2 includes the plurality of terminal biasing parts 8; each terminal biasing part 8 biases its corresponding terminal attachment part 7. That is, the terminal attachment parts 7 are individually biased by the biasing force of their corresponding terminal biasing parts 8, and can individually move in the top-bottom direction. Thus, the first terminals 6a of the first terminal group 6 and the second terminals 11a of the second terminal group 11 individually come in contact with each other stably, and these contact states are maintained favorably. Therefore, the conduction state of the FPC terminal connection structure 10 is maintained favorably, and the electrical performance of the FPC terminal connection structure 10 becomes stable.

Moreover, in the present embodiment, a pair of the terminal attachment part 7 and the terminal biasing part 8, i.e., the elastic terminal area 9 projects downward toward the substrate 3, and thus the first terminal 6a in the terminal attachment part 7 of each elastic terminal area 9 can be stably pressed against the second terminal 11a. Specifically, the terminal biasing part 8 of the flat spring 2 includes a bent portion (the third biasing portion 8c) between the first position 13 and the second position 14; the bent portion is bent to be closer to the substrate 3 as it comes closer to the first position 13. Thus, the terminal attachment part 7 of each elastic terminal area 9 is stably pressed toward the substrate 3 by the terminal biasing part 8. Accordingly, the conduction state of the FPC terminal connection structure 10 is maintained favorably, and the electrical performance of the FPC terminal connection structure 10 becomes stable.

Furthermore, in the present embodiment, the substrate 3 includes the protruding insulating portions 12, and thus it is possible to suppress contact between the terminal attachment parts 7 adjacent in the width direction. That is, it is possible to suppress a short between the first terminals 6a of the first terminal group 6. Therefore, the electrical performance of the FPC terminal connection structure 10 is maintained favorably.

Moreover, in the present embodiment, the base material 4 includes the positioning parts 4b, and thus the flat spring 2 and the FPC 1 can be positioned on the base material 4 by the positioning parts 4b and fastened to the base material 4 with the fastening member 5. Accordingly, assembly is easy. Furthermore, the positioning parts 4b make it possible to suppress corotation of the flat spring 2 and the FPC 1 along with the fastening member 5 when the flat spring 2 and the FPC 1 are fastened to the base material 4. Accordingly, the positioning parts 4b may be rephrased as a rotation stopper.

According to the present embodiment, the positions of the FPC 1, the flat spring 2, and the substrate 3 in the width direction are fixed by the positioning parts 4b, and thus the first terminal group 6 and the second terminal group 11 are stably brought into contact with each other, and the conduction state of the FPC terminal connection structure 10 is maintained favorably, and then the electrical performance of the FPC terminal connection structure 10 becomes stable.

Furthermore, according to the method for manufacturing the FPC terminal connection structure 10 in the present embodiment, pairs of the terminal attachment parts 7 and the terminal biasing parts 8 stacked in the top-bottom direction (i.e., the elastic terminal areas 9) are formed by making, in a state where the flat spring 2 is bonded to and integrated with the FPC 1, slits in the flat spring 2 and the FPC 1; therefore, it is not necessary to do the work of adjusting the positions of the terminal biasing parts 8 on top of the terminal attachment parts 7 when assembled, and it is easy to manufacture thus the FPC terminal connection structure 10. Furthermore, when the flat spring 2 is fastened to the base material 4 with the fastening member 5, the terminal biasing parts 8 stably presses the terminal attachment parts 7 integrally bonded to the terminal biasing parts 8 against the substrate 3, and thus the first terminals 6a in the terminal attachment parts 7 are stably in close contact with the second terminals 11a of the second terminal group 11. Accordingly, the conduction state of the FPC terminal connection structure 10 is maintained favorably, and the electrical performance of the FPC terminal connection structure 10 becomes stable.

It is to be noted that the present invention is not limited to the above-described embodiment, and, for example, as described below, modifications, etc. of the configurations can be made without departing from the scope of the present invention.

In the foregoing embodiment, there is described an example where the terminal attachment part 7 includes the first portion 7a, the second portion 7b, and the third portion 7c, and the terminal biasing part 8 includes the first biasing portion 8a, the second biasing portion 8b, and the third biasing portion 8c; however, they are not limited to this.

FIG. 4 illustrates a first modification example of the FPC terminal connection structure 10 described in the foregoing embodiment. In this first modification example, the elastic terminal area 9 is formed into a C-shape protruding toward the substrate 3 on the bottom, i.e., a curved shape. That is, the terminal attachment part 7 is formed into a curved shape protruding toward the bottom, and the terminal biasing part 8 is also formed into a curved shape protruding toward the bottom.

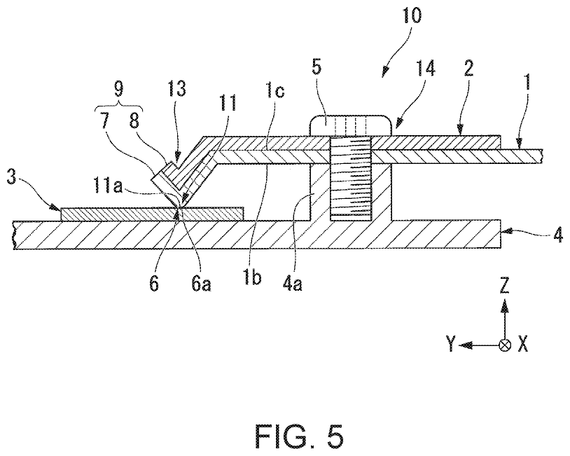

FIG. 5 illustrates a second modification example of the FPC terminal connection structure 10 described in the foregoing embodiment. In this second modification example, the elastic terminal area 9 is formed into a V-shape protruding toward the substrate 3 on the bottom, i.e., a bend. That is, the terminal attachment part 7 is formed into a bend protruding toward the bottom, and the terminal biasing part 8 is also formed into a bend protruding toward the bottom.

Also in the above-described first and second modification examples, similar workings and effects to the foregoing embodiment are obtained.

Furthermore, in the foregoing embodiment, there is described an example where the flat spring 2 is metallic; however, the material of the flat spring 2 is not limited to this. For example, the flat spring 2 may be an elastically deformable resin plate member or something.

Moreover, there is described an example where the fastening member 5 is a screw; the fastening member 5 is not limited to this. For example, the fastening member 5 may be a snap-fit or something.

Furthermore, without departing from the scope of the present invention, the configurations (components) described in the foregoing embodiment, the modification examples, explanatory notes, etc. may be combined, or addition, omission, and replacement of a configuration, and other modifications may be made. Moreover, the present invention is not limited by the foregoing embodiment, and is limited only by claims.

As has been described, the present invention provides a simplified, easy-to-assemble FPC terminal connection structure, and a method of making such FPC terminal connection structure.

While the invention has been particularly shown and described with reference to a preferred embodiment, it will be understood by those skilled in the art that various changes in form and detail may be made therein without departing from the spirit and scope of the invention.

What is claimed is:

1. A flexible printed circuit (FPC) terminal connection structure, comprising:
a base material;
a substrate secured to said base material, wherein said substrate includes a second terminal group on one surface thereof;
a FPC having a first terminal group on a first surface thereof, respective corresponding terminals of said first terminal group and said second terminal group being in contact with each other;
a flat spring disposed on top of a first position that is a position that interferes with at least said first terminal group on a second surface of said FPC; and
a fastening member for fastening said flat spring and said FPC to said base material at a second position different from said first position, wherein by said flat spring being fastened to said base material with said fastening member, said first terminal group of said FPC is biased toward said second terminal group of said substrate.

2. The FPC terminal connection structure of claim 1, wherein said FPC includes a plurality of terminal attachment parts disposed in a width direction perpendicular to an extending direction and a thickness direction of said FPC so as to be spaced apart from one another.

3. The FPC terminal connection structure of claim 2, wherein said flat spring includes a plurality of terminal biasing parts disposed in said width direction so as to be spaced apart from one another.

4. The FPC terminal connection structure of claim 3, wherein said terminal biasing parts are disposed on top of said terminal attachment parts at said first position, wherein said first terminal group includes a plurality of first terminals, and said first terminals are disposed in said terminal attachment parts.

5. The FPC terminal connection structure of claim 2, wherein said substrate includes a protruding insulating portion disposed between said terminal attachment parts adjacent in said width direction.

6. The FPC terminal connection structure of claim 1, wherein said flat spring includes a bent portion between said first position and said second position, said bent portion being bent to be closer to said substrate towards said first position.

7. The FPC terminal connection structure of claim 1, wherein said base material includes a positioning part that is able to be in contact with at least either said flat spring or said FPC in a width direction perpendicular to an extending direction and a thickness direction of said FPC at a position closer to said second position than said first position.

8. A method comprising:
bonding a flat spring to at least a first position on a second surface of a flexible printed circuit (FPC) and integrating said flat spring with said FPC;
forming a plurality of spaced-apart elastic terminal areas by making slits in said flat spring and said FPC at said first position; and
fastening said flat spring and said FPC to said base material at said second position with said fastening member and bringing said first terminal group of said FPC and said second terminal group of said substrate into contact with each other, wherein said elastic terminal areas each include said terminal attachment part and said terminal biasing part, and by said flat spring being fastened to said base material with said fastening member, said first terminals disposed in said terminal attachment parts of said elastic terminal areas are pressed against said second terminal group by biasing force of said terminal biasing parts.
